(19) United States
(12) Patent Application Publication
(10) Pub. No.: US 2023/0261435 A1
(43) Pub. Date: Aug. 17, 2023

(54) OPTOELECTRONIC DEVICE AND METHOD OF PREPARATION THEREOF

(71) Applicant: ROCKLEY PHOTONICS LIMITED, Altrincham Cheshire (GB)

(72) Inventors: Frank PETERS, Dublin (IE); Ludovic CARO, Dublin (IE)

(21) Appl. No.: 18/015,026

(22) PCT Filed: Jul. 7, 2021
(86) PCT No.: PCT/EP2021/068757

§ 371 Date: Jan. 6, 2023

(30) Foreign Application Priority Data
Jul. 9, 2020 (GB) 2010596.1
May 25, 2021 (GB) 2107440.6

(51) Int. Cl. H01S 5/026; H01S 5/042; H01S 5/22

(52) U.S. Cl. CPC H01S 5/026; H01S 5/04256; H01S 5/22

(57) ABSTRACT

An optoelectronic device. The optoelectronic device comprising: a plurality of waveguide ridges provided in an array, each waveguide ridge extending away from a semiconductor bed; a plurality of upper contacts, each electrically connected to an upper surface of a respective waveguide ridge, said upper surface being located distal from the semiconductor bed; and a plurality of lower contacts, each located between a respective pair of waveguide ridges and electrically connected to the semiconductor bed.

### RELATED APPLICATIONS

The present application claims priority to, and the benefit of, GB 2010596.1 filed 9 Jul. 2020 (09/07/2020), the contents of which are incorporated herein by reference in their entirety.

### FIELD OF THE INVENTION

The present invention relates to an optoelectronic device and a method of preparation thereof.

### BACKGROUND

In some photonic applications, very dense arrays of gain chips are desired. By coupling these gain chips with grating, distributed feed-back (DFB)/distributed Bragg-reflector (DBR) lasers can be formed. These chips should have multiple gain blocks (lasers) adjacent to each other, and close as possible. Typically only one will be operated at a time, and therefore thermal crosstalk is not an issue.

However when the lasers are located in close proximity, the resistance of the devices will increase due to less metal on the electrical contacts. There is a problem then, in how to get good working (e.g. low resistance) lasers that are as close as possible together (e.g. side to side) so that a small chip can contain multiple gain blocks.

The present invention has been devised in light of the above considerations.

### SUMMARY

Accordingly, in a first aspect, embodiments of the present invention provide an optoelectronic device comprising:

a plurality of waveguide ridges provided in an array, each waveguide ridge extending away from a semiconductor bed;

a plurality of upper contacts, each electrically connected to an upper surface of a respective waveguide ridge, said upper surface being located distal from the semiconductor bed; and

a plurality of lower contacts, each located between a respective pair of waveguide ridges and electrically connected to the semiconductor bed.

Such an optoelectronic device demonstrates reduced resistance, and so facilitates a higher density of components.

The optoelectronic may have any one or, to the extent that they are compatible, any combination of the following optional features.

Each waveguide ridge may provide a laser gain medium such that, when coupled to a corresponding grating, a plurality of distributed feedback lasers or distributed Bragg-reflector lasers are formed.

Each upper contact may be spaced from a respective lower contact by an insulating layer. The insulating layer may be a dielectric.

Each lower contact may be separated from the respective pair of waveguide ridges by an insulating layer. Each lower contact and its respective insulating layer may fill the space between the respective pair of waveguide ridges. The insulating layer may be a dielectric.

Each upper contact may be situated on an opposing side of its respective waveguide ridge to the semiconductor bed. Each upper contact may have a width which is wider than a corresponding width of its respective waveguide ridge.

Each lower contact may be electrically connected to one or more contact pads, said or each contact pad may have an exposed surface suitable for connection to an external driver.

Each pair of waveguide ridges may be separated by a respective separator wall, and each lower contact may be adjacent to at least a portion of a respective separator wall.

Each upper and/or each lower contact may have a width of at least 15 μm, said width may be measured in a direction transversal to a guiding direction of the plurality of waveguide ridges.

Each upper contact may extend through an opening in an insulating layer to electrically connect to the upper surface of each waveguide ridge.

Each upper and/or each lower contact may have a height of at least 1.5 μm, in some examples at least 2 μm, said height may be measured in a direction from the semiconductor bed towards the upper contact.

Each upper contact may be electrically isolated from the other upper contact.

Each lower contact may be in electrical connection with the other lower contacts.

The upper contacts and/or lower contacts may be made of metal.

The upper contacts and/or the lower contacts may be made from a doped semiconductor, for example a heavily doped semiconductor region.

In a second aspect, embodiments of the present invention provide a method of preparing an optoelectronic device, the optoelectronic device comprising a plurality of waveguide ridges provided in an array, each waveguide ridge extending away from a semiconductor bed; the method comprising steps of:
(a) depositing a plurality of lower contacts, each located between a respective pair of waveguide ridges and electrically connected to the semiconductor bed; and
(b) depositing a plurality of upper contacts, each electrically connected to an upper surface of a respective waveguide ridge, said upper surface being located distal from the semiconductor bed.

Such a method results in an optoelectronic device which demonstrates reduced resistance, and so facilitates a higher density of components.

The method may have any one or, to the extent that they are compatible, any combination of the following optional features.

The method may further include a step, performed before step (a), of growing an insulator on an exposed surface of the optoelectronic device, and etching an opening in the insulator, exposing a surface of the semiconductor bed, for each lower contact to be deposited in during the subsequent deposition step.

Step (a) may include an initial step of providing a liner at least partially up a sidewall of each waveguide ridge, and along the semiconductor bed between respective pairs of waveguide ridges. Step (a) may further include a step of depositing further contact material on at least the liner such that each lower contact and a respective insulating layer, the insulating layer being located between the lower contact and its respective pair of waveguide ridges, fills the space between the respective waveguide ridges.

Step (b) may be performed after step (a), and may include an initial step of growing an insulator layer over the plurality of lower contacts. The insulator layer may also be grown over the upper surfaces of each waveguide ridge, and step (b) may further include etching an opening in the insulator layer to expose the upper surface of each waveguide ridge, said etching occurring before the deposition of the upper metal contacts.

Steps (a) and (b) may be performed in a simultaneous deposition step. The simultaneous deposition step may be performed through angled electroplating, and a plurality of separator walls, each provided between a respective pair of waveguide ridges, may provide a shadow over at least a part of a space between each separator wall and a one of the respective pair of waveguide ridges, such that a gap exists between each lower contact and respectively adjacent upper contacts.

The upper contacts and/or lower contacts may be made of metal.

The upper contacts and/or the lower contacts may be made from a doped semiconductor, for example a heavily doped semiconductor region.

In a third aspect, embodiments of the invention provide an optoelectronic device prepared using the method of the second aspect.

Further aspects of the present invention provide: a computer program comprising code which, when run on a computer, causes the computer to perform the method of the second aspect; a computer readable medium storing a computer program comprising code which, when run on a computer, causes the computer to perform the method of the second aspect; and a computer system programmed to perform the method of the second aspect.

### BRIEF DESCRIPTION OF THE DRAWINGS

Embodiments of the invention will now be described by way of example with reference to the accompanying drawings in which:

FIG. 1A shows a partial cross-sectional view of an optoelectronic device;

FIG. 1B shows a top-down view of the optoelectronic device of FIG. 1A;

FIGS. 2A-36B show various process steps of the optoelectronic device of FIGS. 1A and 1B, where A figures show partial cross-sections and B figures show top-down views; and

FIGS. 37-39 show various process steps of a variant optoelectronic device in cross-section.

### DETAILED DESCRIPTION AND FURTHER OPTIONAL FEATURES

Aspects and embodiments of the present invention will now be discussed with reference to the accompanying figures. Further aspects and embodiments will be apparent to those skilled in the art.

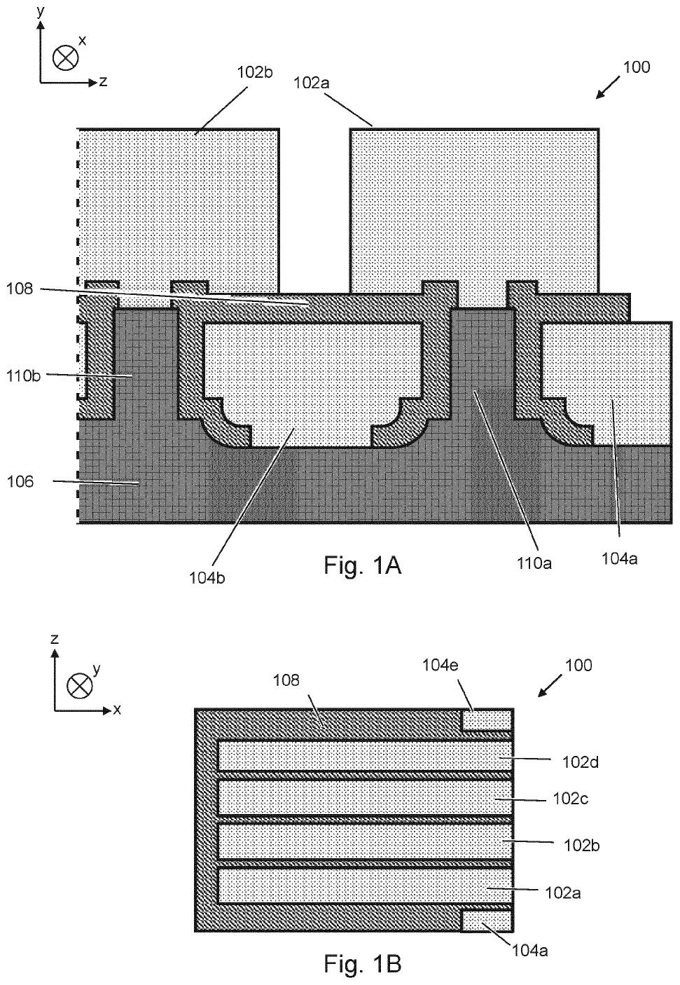

FIG. 1A shows a partial cross-sectional view of an optoelectronic device 100 and FIG. 1B shows a top-down view of the optoelectronic device of FIG. 1A. The device includes a semiconductor bed or substrate 106, from which a plurality of waveguide ridges 110a-d extend. Each waveguide ridge is electrically connected, on an upper surface, to a respective upper metal contact 102a-102d. The optoelectronic device also includes a plurality of lower metal contacts 104a-104e, which electrically connect to the semiconductor bed 106 at positions between pairs of waveguide ridges (asides from first 104a, and last 104e lower metal contacts which are situated at the edge of the device). The first 104a and last 104e lower metal contacts also provide contact pads for wire bonding or similar.

The upper metal contacts 102a-102d are spaced from the lower metal contact layers 104a-104e by an insulator layer 108, formed for example from silicon nitride, an oxide, or silicon oxide. The semiconductor bed in this example is formed from a III-V semiconductor (e.g. InP or GaAs), and the metal upper and lower contact layers are formed from a mixture of gold and titanium.

As can be seen in the top-down view, the optoelectronic device 100 includes four upper metal contacts: 102a-102d which respectively electrically connect to four waveguide ridges 110a-110d and form lasers. The upper metal contacts are electrically insulated from one another. In contrast, the lower metal contacts 104a-104e are electrically connected to each other, and so contact pads located on lower metal contacts 104a and 104e can be used to apply a bias to all lower metal contacts.

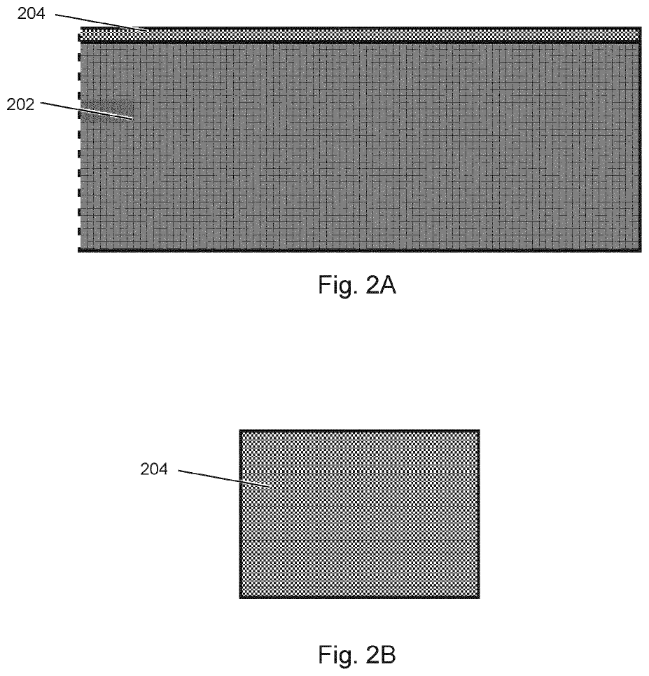

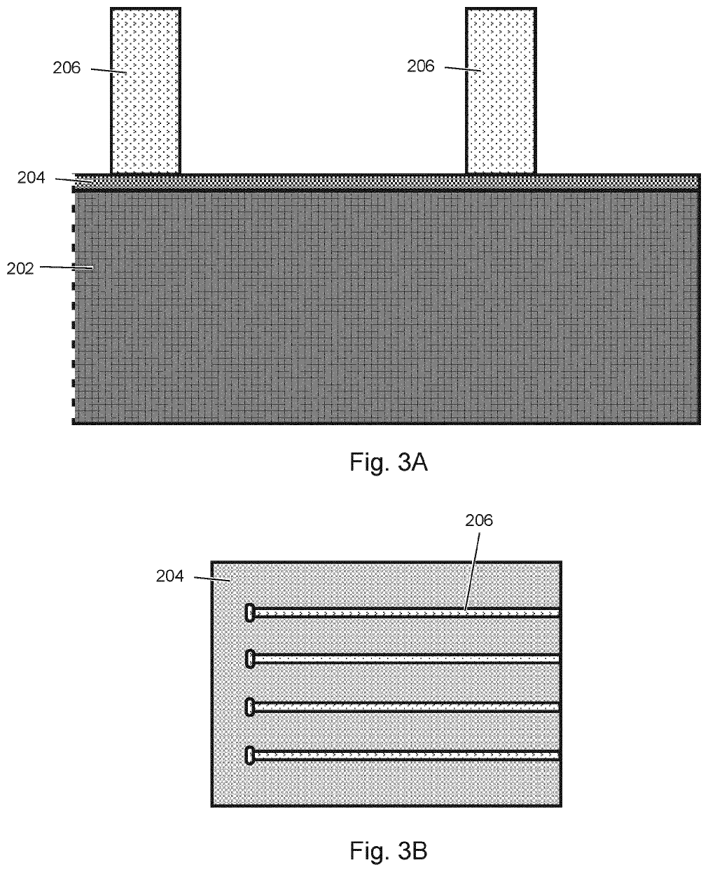

FIGS. 2A-36B show various process steps according to one method for producing the optoelectronic device of FIGS. 1A and 1B, where A figures show partial cross-sections and B figures show top-down views. In a first step, shown in FIGS. 2A and 2B, a semiconductor substrate 202 is coated in an oxide hard mask 204. Next, as shown in FIGS. 3A and 3B, photoresist 206 is deposited and patterned (e.g. through use of photolithography) to define the waveguides of the end device. That is, each section of the photoresist 206 is generally rectangular in shape with the long axis of the photoresist being aligned with the guiding direction of the waveguide when formed. The photoresist also defines, at an end of the waveguide which is not directly adjacent to a facet of the output device, a reflector or mirror. This portion is wider than the remaining photoresist.

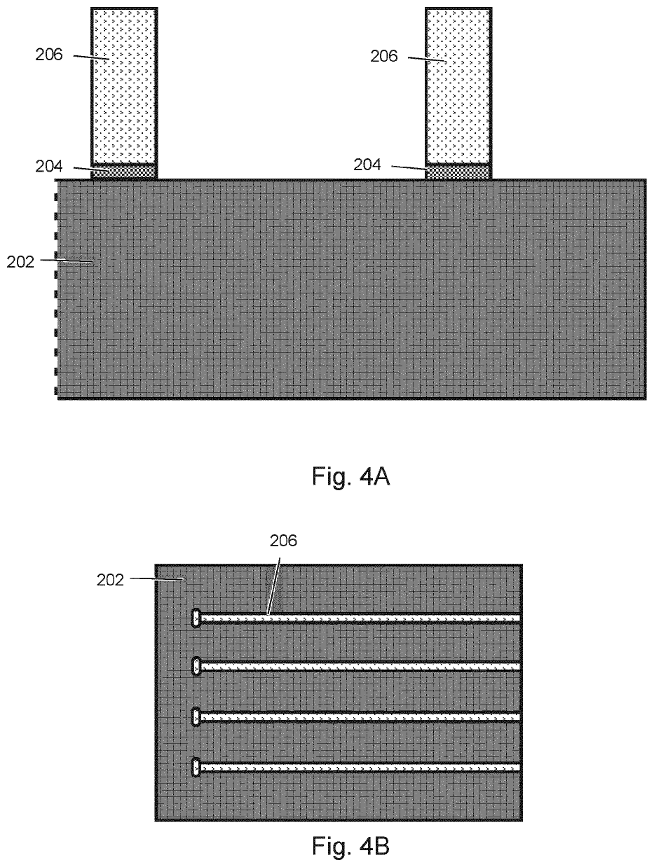

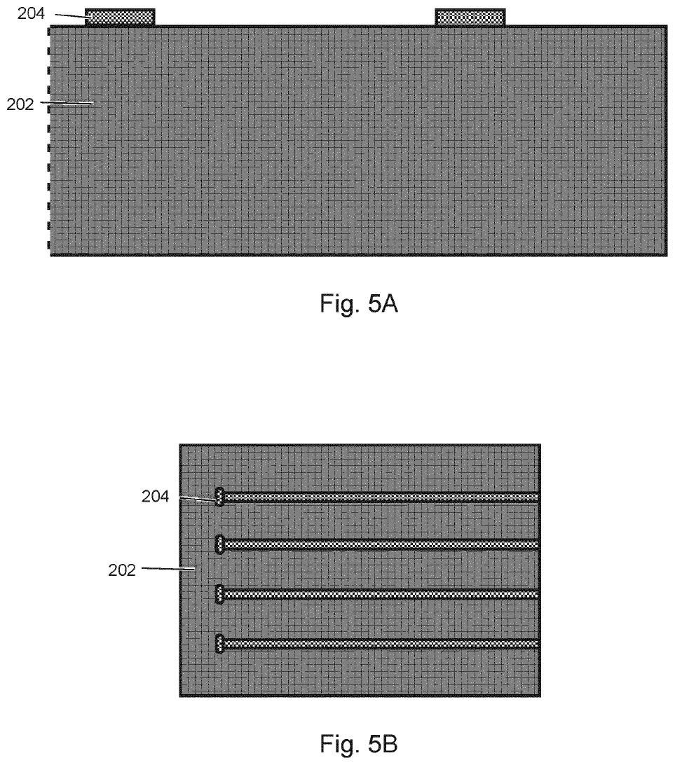

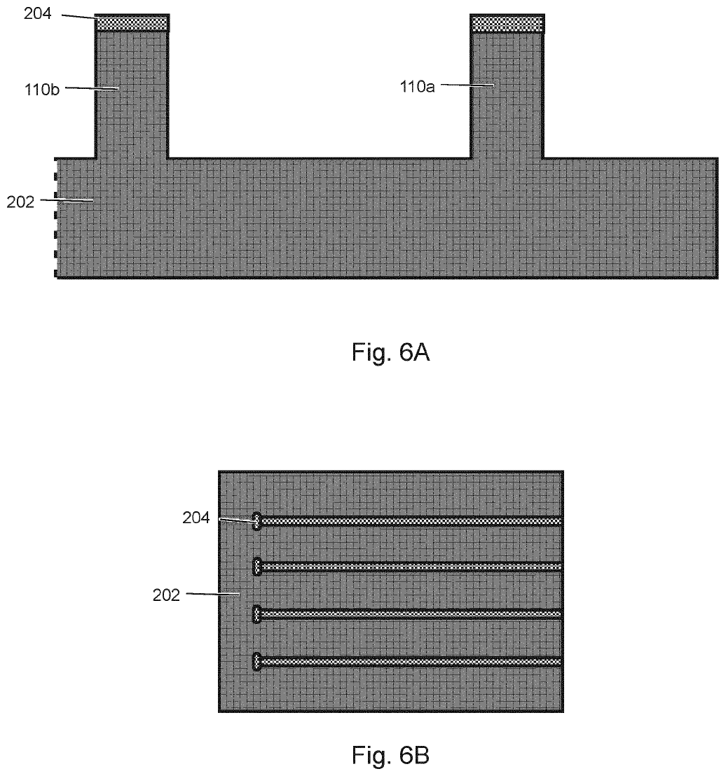

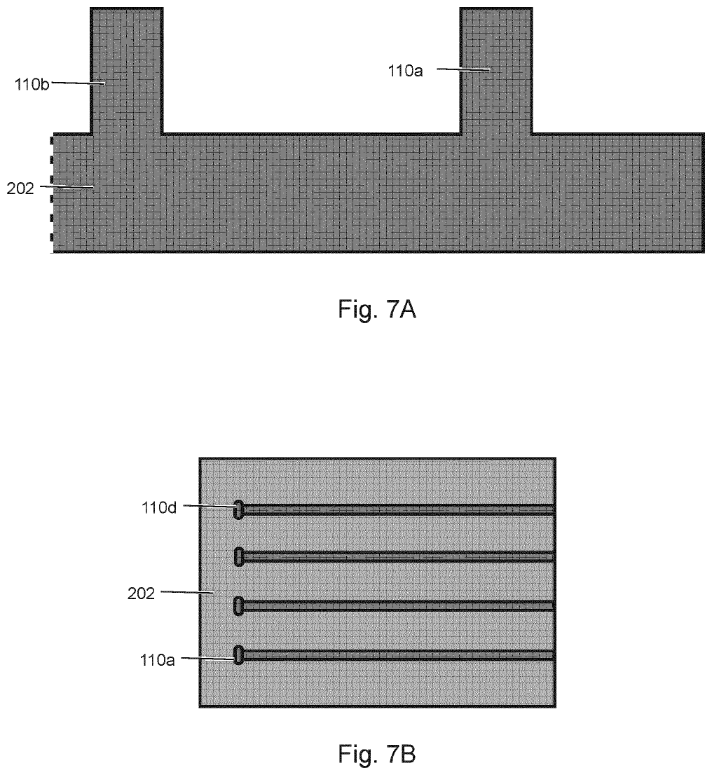

After the photoresist 206 has been applied, the exposed oxide hard mask 204 is etched away. The result of this is shown in FIGS. 4A and 4B. The photoresist is then removed, as shown in FIGS. 5A and 5B so that the remaining oxide hard mask 204 is exposed. An etch is then performed (preferably a dry etch) to remove a portion of the semiconductor 202 and thereby define the waveguides 110a-110d. The result of this is shown in FIGS. 6A and 6B. The oxide hard mask is then removed as illustrated in FIGS. 7A and 7B.

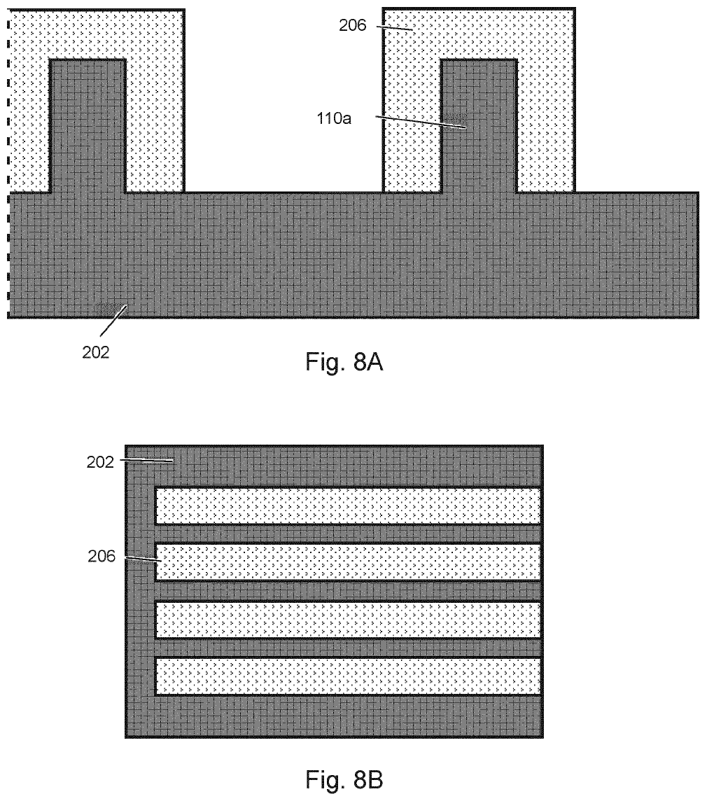

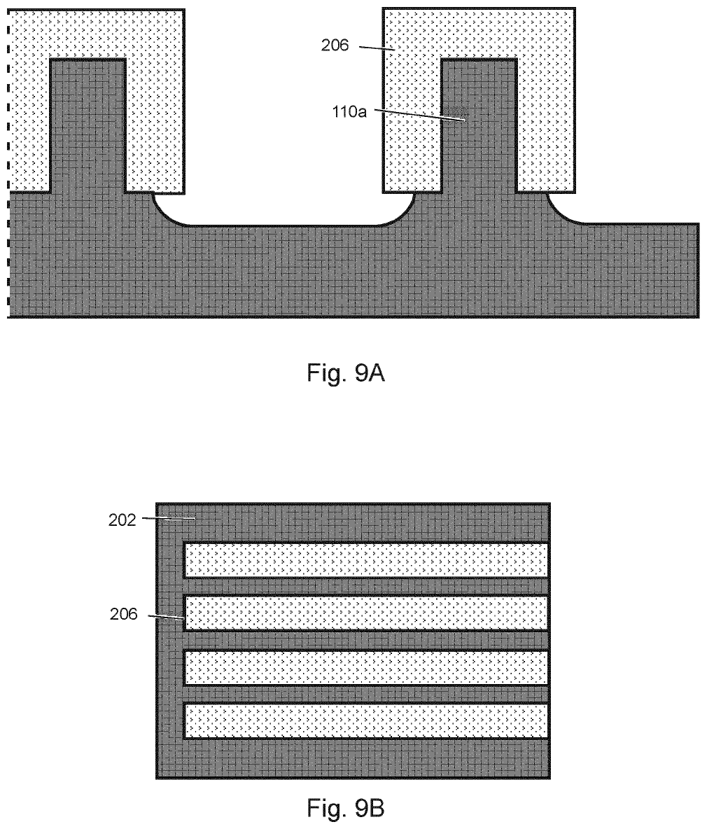

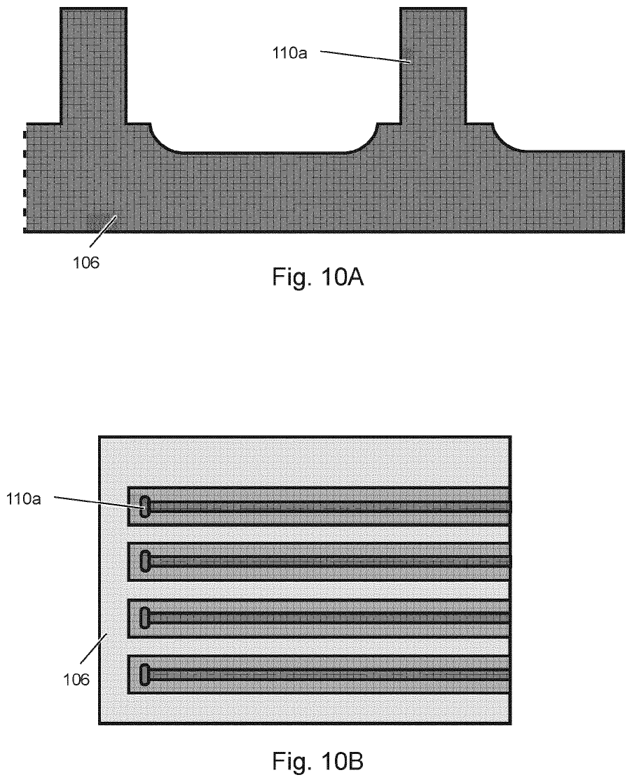

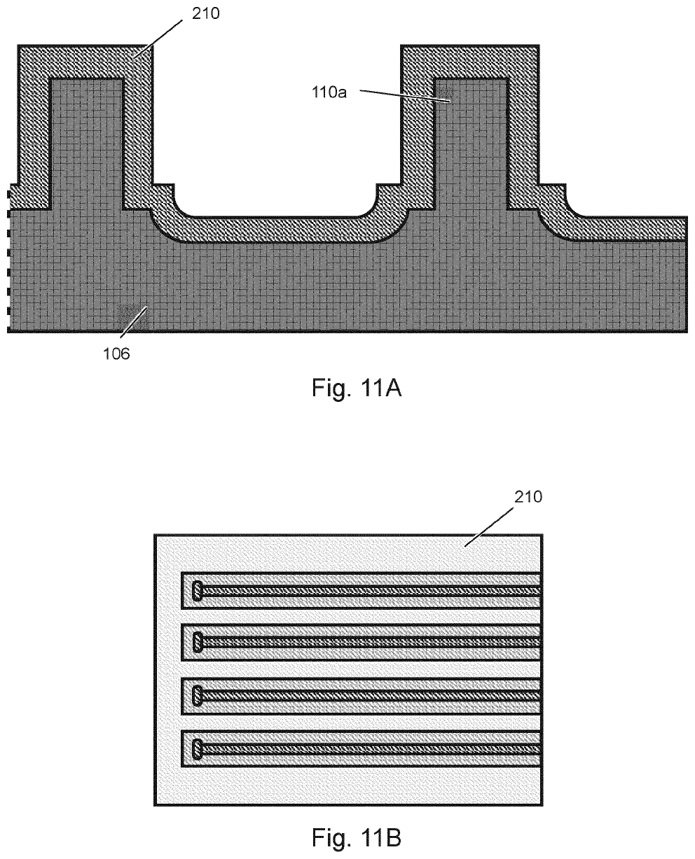

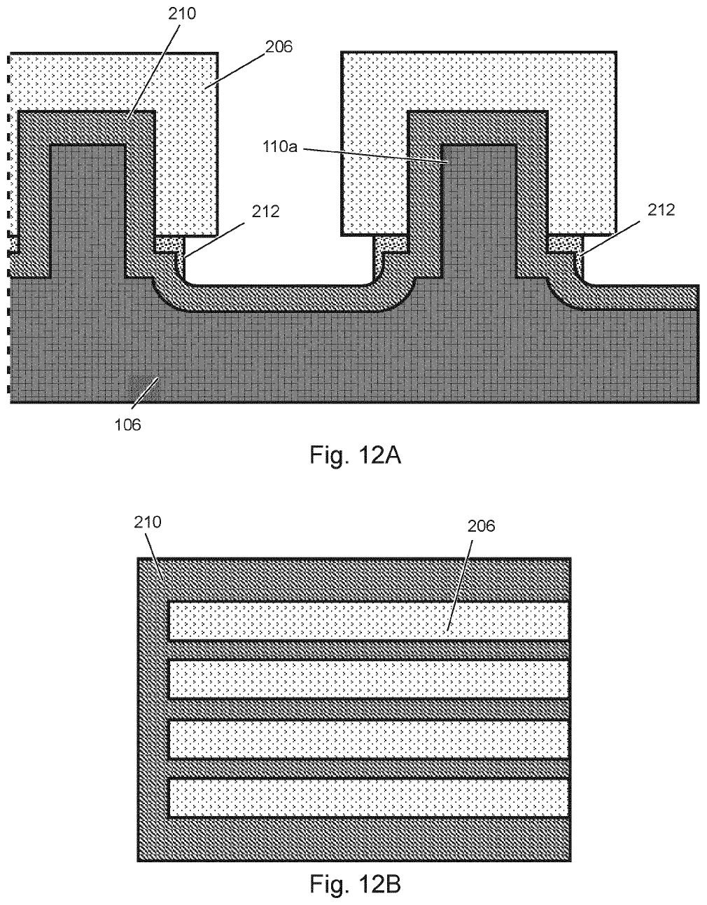

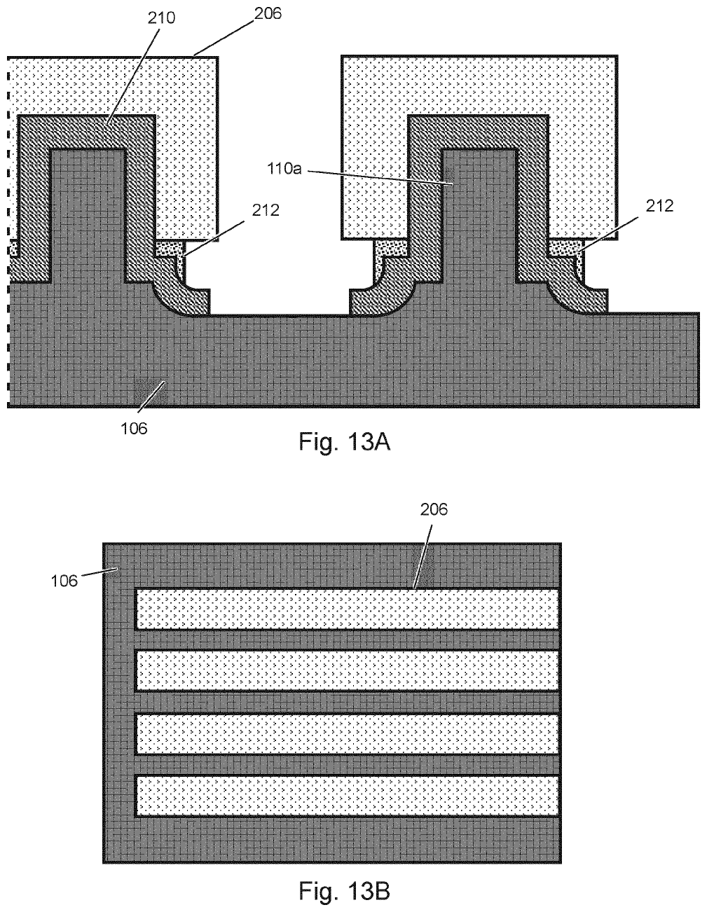

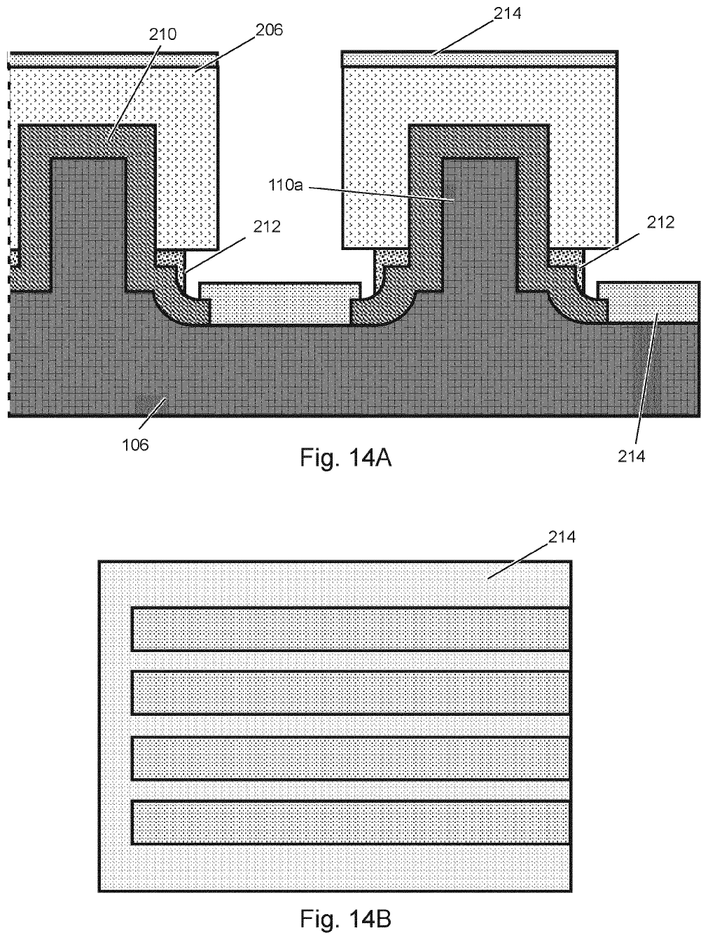

Further photoresist 206 is then deposited and patterned so as to encapsulate the waveguides 110a-110d as shown in FIGS. 8A and 8B. A wet or dry etch is then applied, to partially undercut the exposed semiconductor 202 as shown in FIGS. 9A and 9B. The photoresist is then removed as shown in FIGS. 10A and 10B. The final geometry of the semiconductor bed 106 is defined at this stage. Next, in a step shown in FIGS. 11A and 11B, an insulator 210 (such as silicon nitride or silicon oxide) is grown or deposited over the exposed surfaces of the device. In a subsequent step polydimethylglutarimide (PMGI) 212 and further photoresist 206 is applied to define a space which will subsequently become the lower metal contacts. The result of this is shown in FIGS. 12A and 12B. The application of a further photoresist significantly improves lift-off of the metal. However, as will be appreciated, alternative methods can be used, such as a negative resist or simple etch to open the dielectric (using photoresist) and then deposition of metal followed by a metal etch. Subsequently, a further etch (either wet or dry) is performed to remove the unmasked insulator 210, notably including the insulator located directly between portions of the photoresist 206. The result of this is shown in FIGS. 13A and 13B. This exposes a portion of the semiconductor bed 106, which is then covered in deposited seed metal 214 to begin the formation of the n-contact, as shown in FIGS. 14A and 14B. Before deposition of the seed metal, a short etch may be performed to remove a few monolayers of the semiconductor (especially the layers which may have been oxidised, and so the etchant may be hydrofluoric acid based).

After the metal is deposited, the photoresist and PMGI are removed (e.g. via lift-off) so that only the metal 214 immediately adjacent to the semiconductor bed 106 is retained. Notably, due to the recess formed by the undercut PMGI, once the metal is deposited a gap remains.

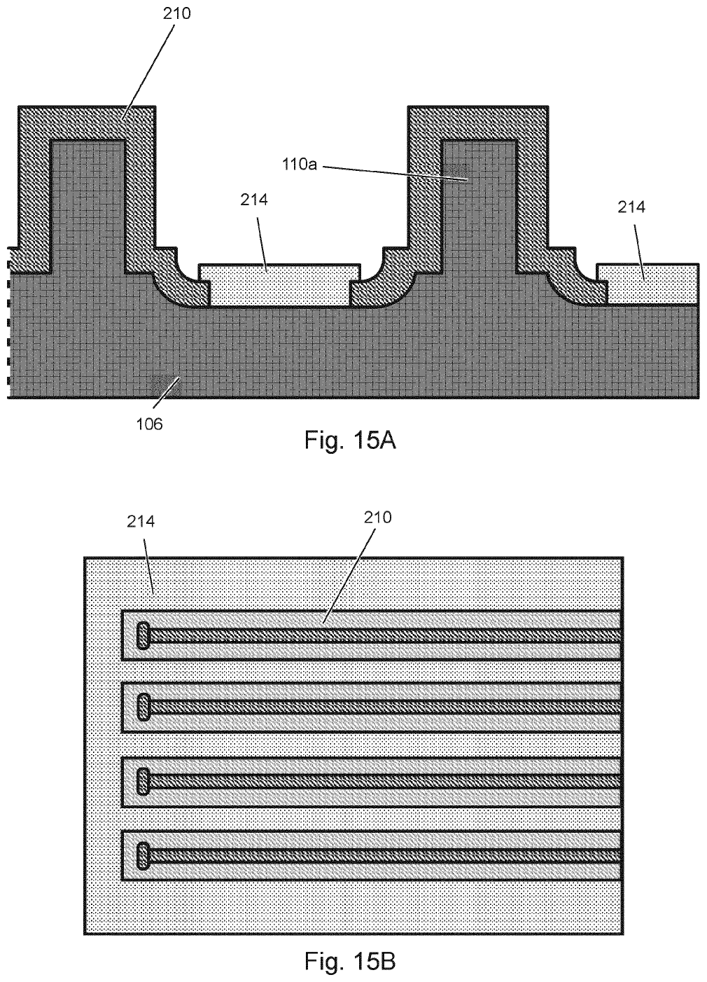

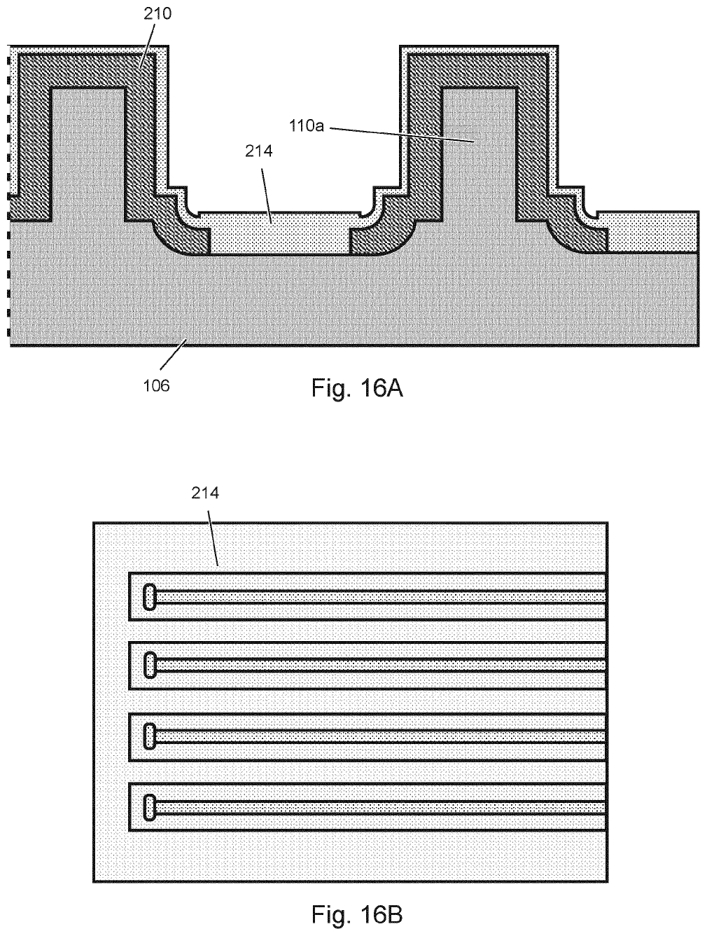

The sample can then be placed in a solvent bath and this gap provides an access point for the solvent to reach the PMGI and photoresist layers. Once these layers are gone, all the metal that was on top of them (from the deposition step) is no longer physically connected to the device and can float away. This is shown in FIGS. 15A and 15B. Next, in a step shown in FIGS. 16A and 16B, further metal 214 is deposited up the sidewalls and over the upper surface of the waveguides 110a. The further metal, in this example, is sputtered as a 20 nm thick titanium layer and a 50 nm thick gold layer.

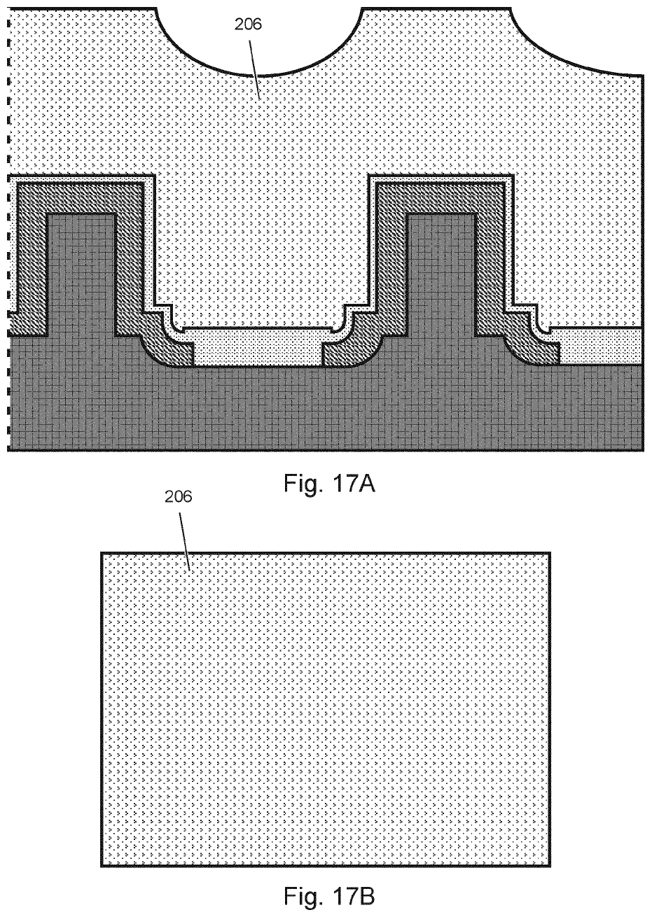

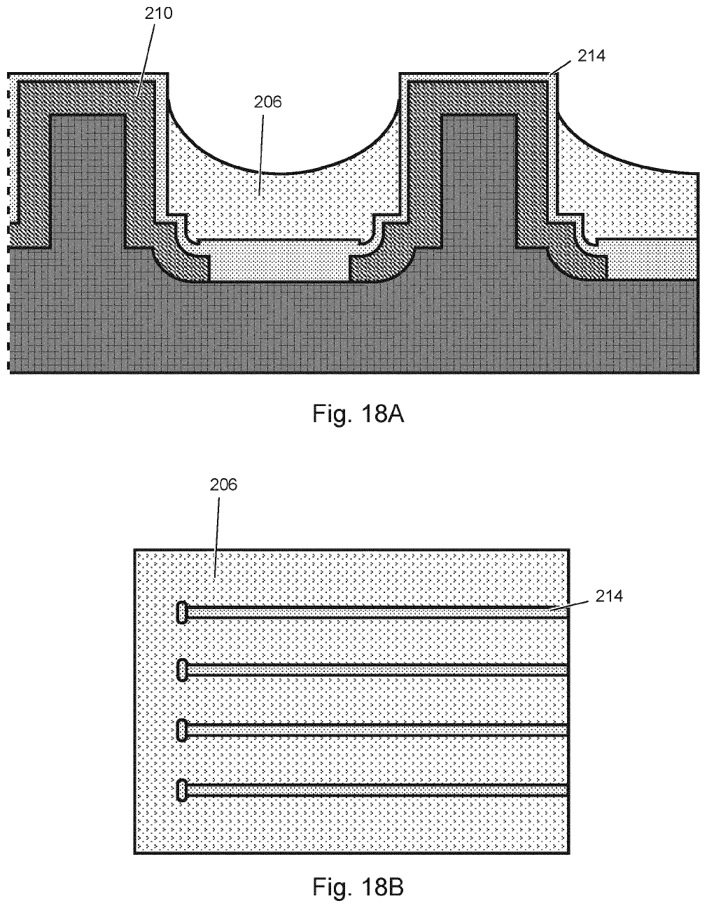

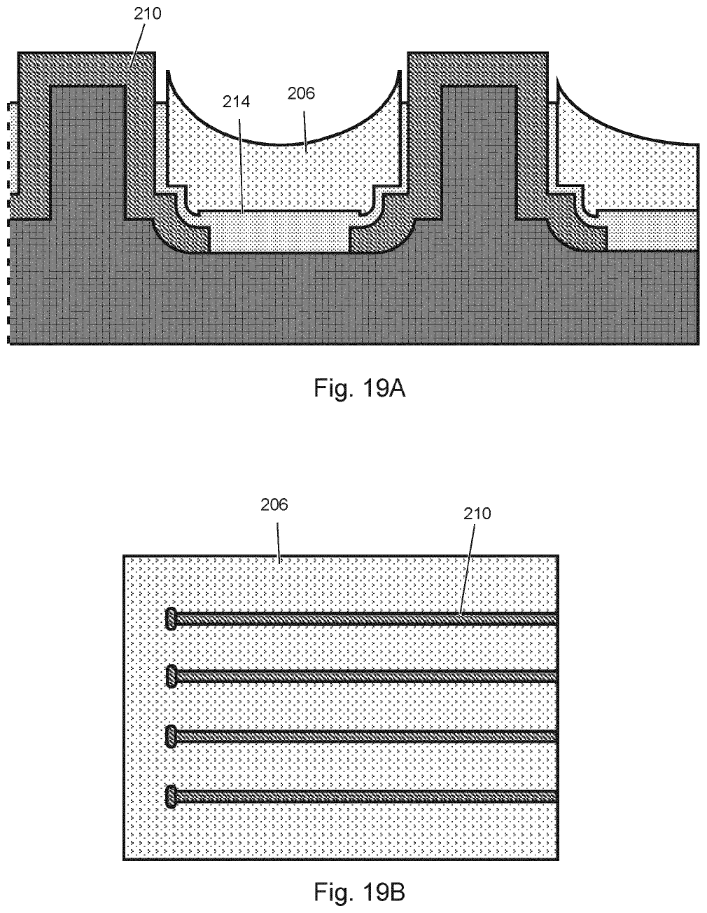

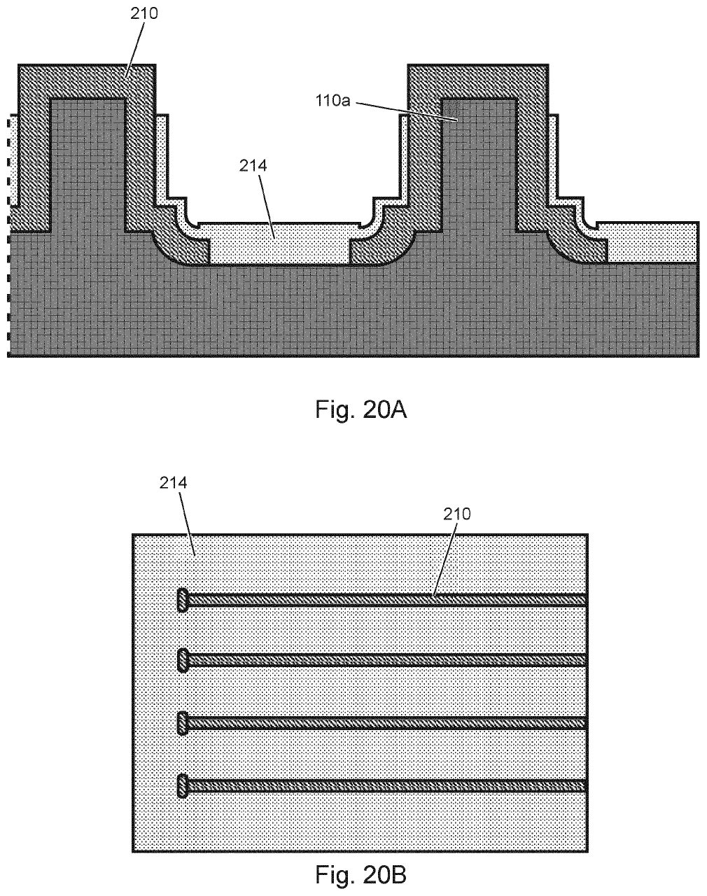

Subsequently a relatively thick photoresist layer 206 is deposited over the upper surface of the device. Instead of photoresist, PMGI or a benzocyclobutene resin could be used. The result of this is shown in FIGS. 17A and 17B. This relatively thick layer is then etched back to reveal the top of the waveguides as shown in FIGS. 18A and 18B. This allows for a partial etch of the metal 214, whereby the exposed metal 214 is removed from the waveguides. This is shown in FIGS. 19A and 19B. The photoresist is then removed as shown in FIGS. 20A and 20B.

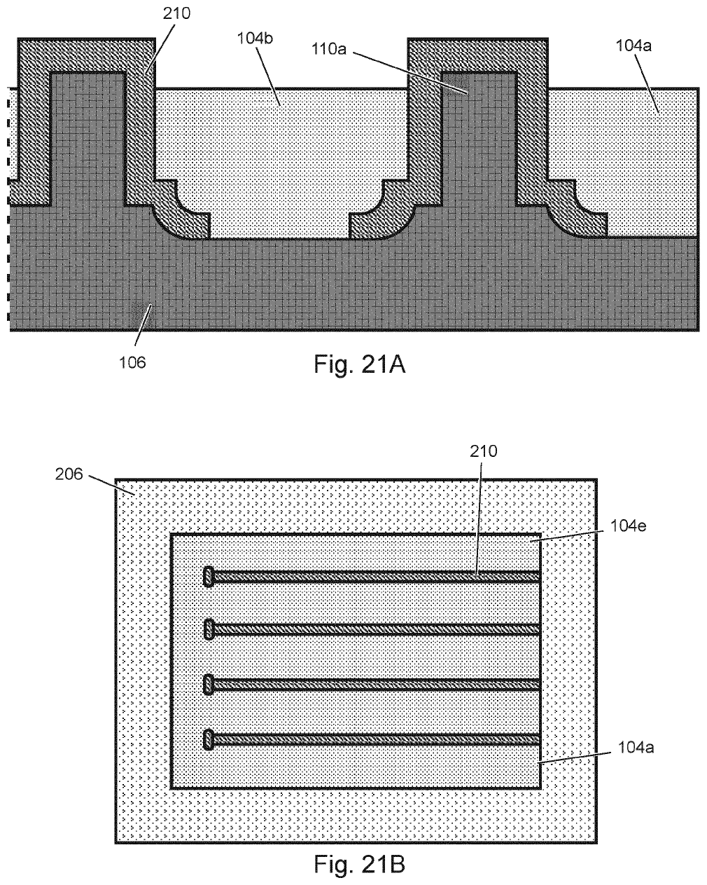

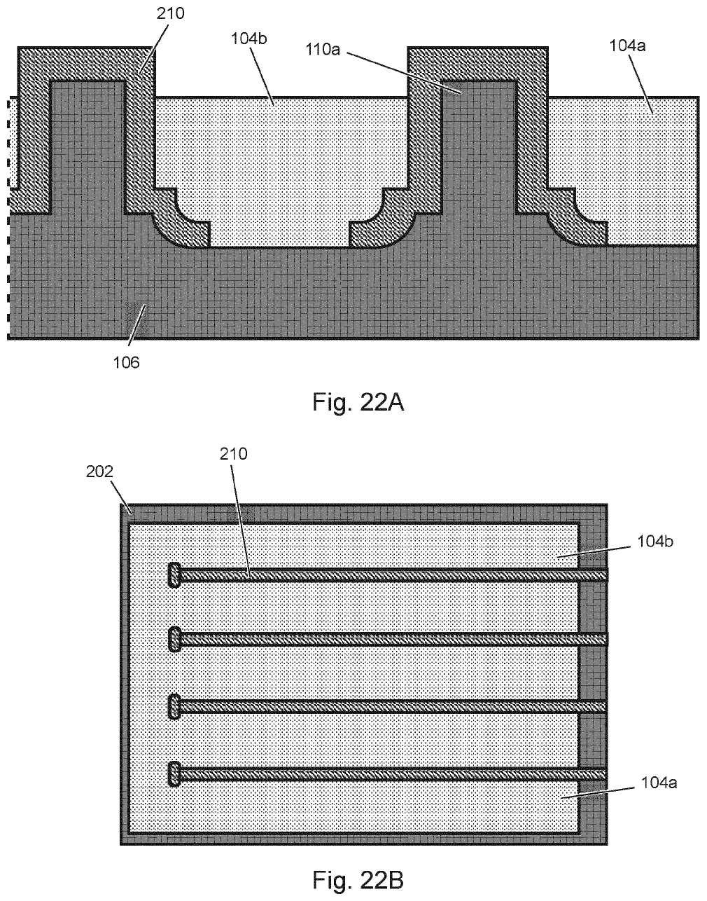

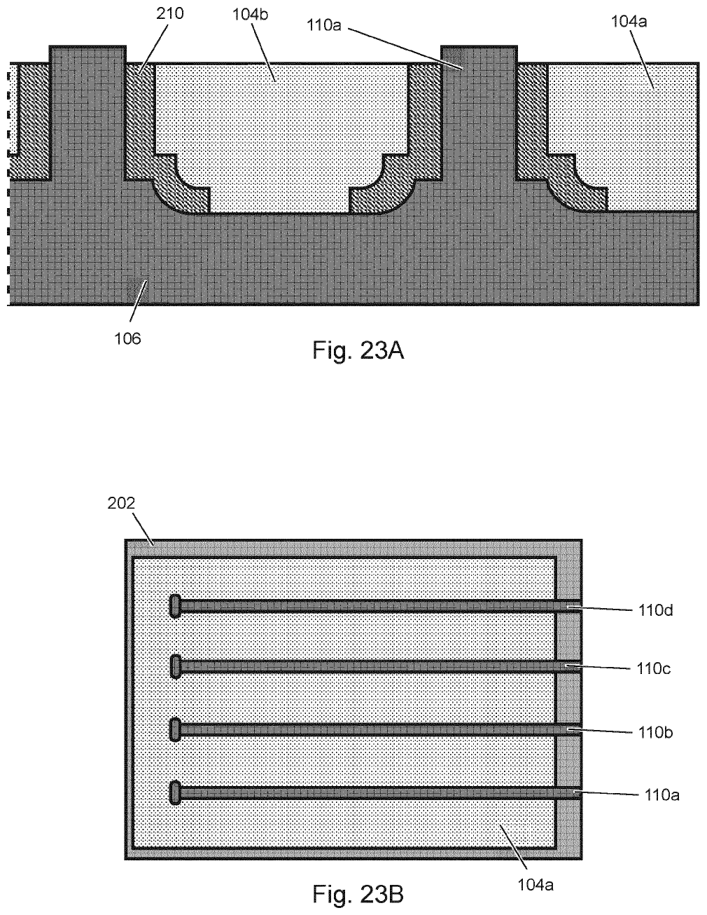

Next, a further photoresist 206 is deposited and patterned as shown in FIGS. 21A and 21B (21B showing this, as the photoresist once patterned is not visible in the section view of FIG. 21A). The photoresist covers an outer perimeter of the device, leaving the waveguides exposed. The previous metal seed is then plated to provide the final lower metal contacts 104a-104e, and in this example are around 2 μm thick and provide the n-contacts. The photoresist is then removed, and the metal etched to remove connections between adjacent chips, as shown in FIGS. 22A and 22B. In detail, at the step illustrated in FIG. 20B there is metal over the entire device asides from on the ridges. In FIG. 21B, the metal within the large outer rectangle is plated and therefore thicker than other portions. In FIG. 22B, after removal of the photoresist and a short etch, all of the metal which was under the photo resist is now etched away. Therefore, the outside of the rectangle is now free of metal. This means that all of the n-contacts within a chip are connected (e.g. as shown in FIG. 22B) but the metal does not extend to an adjacent chip. This is useful when cleaving, or preparing an MTP coupon, where extra metal outside of the chip or coupon could be a problem. A self-aligned etch is then performed to remove the insulator 210 which extends beyond the upper surface of the lower metal contacts 104a, 104b, so that an exposed upper region of each waveguide 110a-110d is provided. The result of this is shown in FIGS. 23A and 23B.

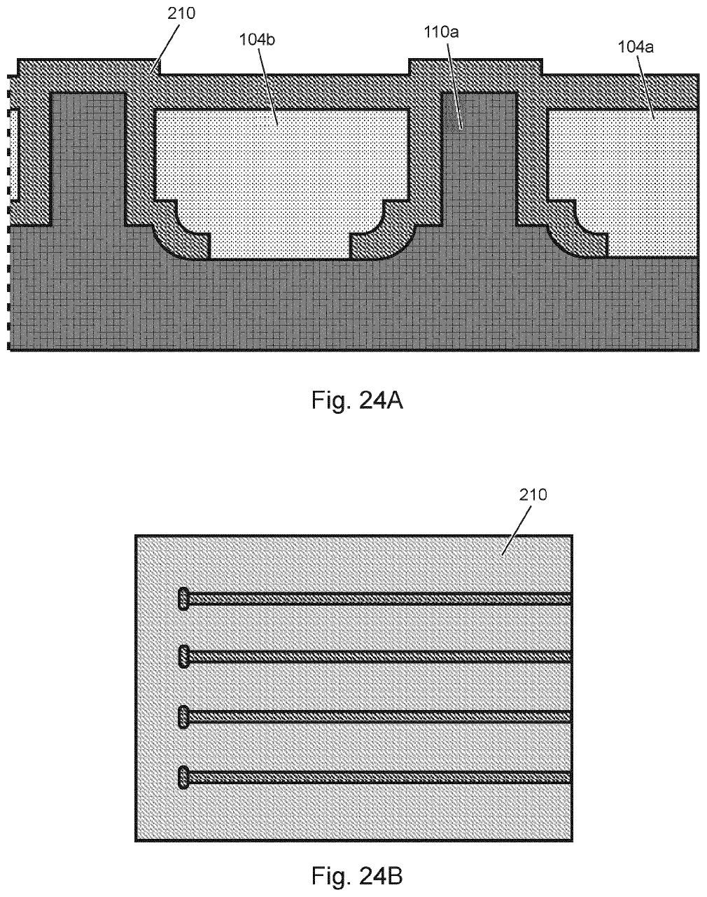

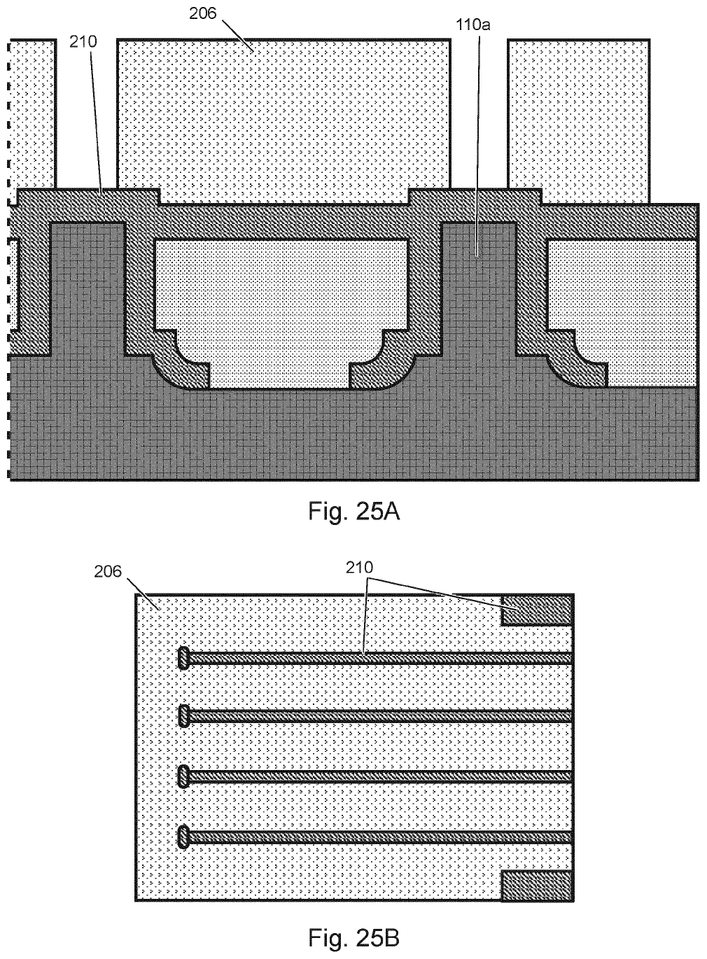

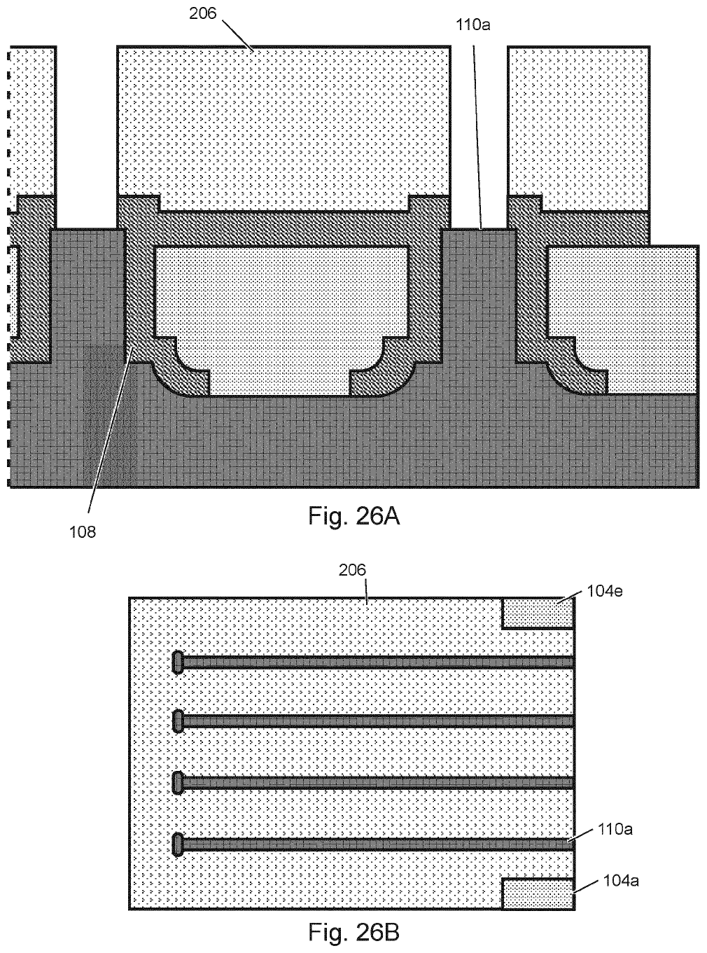

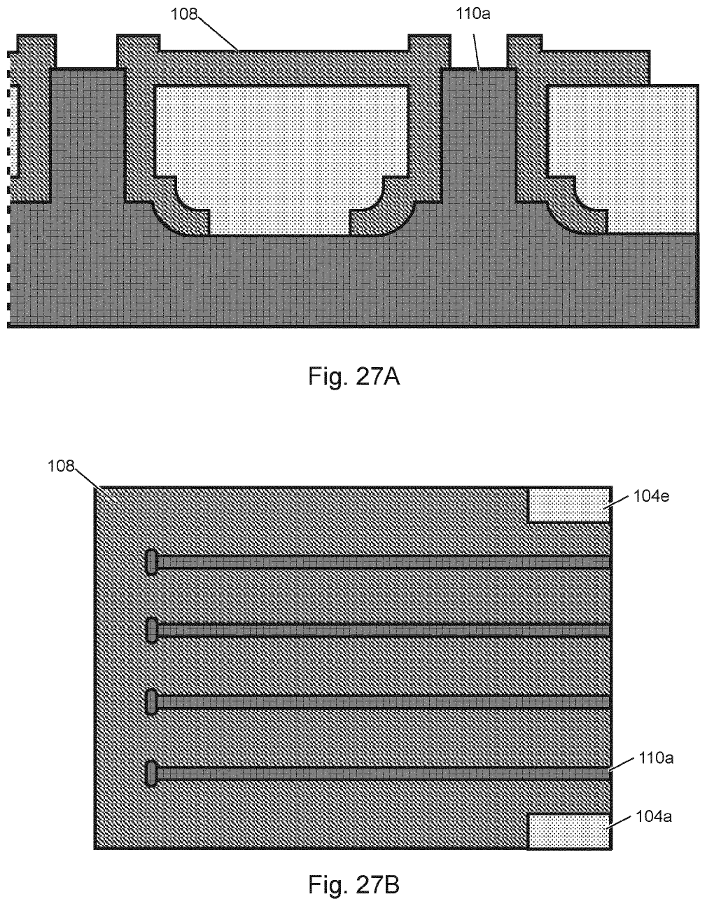

In a further step, shown in FIGS. 24A and 24B, further insulator 210 is provided (through growth or deposition). Photoresist 206 is then deposited and patterned to leave channels aligned with the waveguides 110a-110d as shown in FIGS. 25A and 25B, as well as exposing the insulator 210 above the lower contact pads 104a and 104e. The insulator 210 is then etched away in these portions, exposing an upper surface of the waveguides 110a-110d as well as the lower contact pads 104a and 104e. The result of this is shown in FIGS. 26A and 26B. This step also defines the final geometry of the insulator 108. The photoresist is then removed as shown in FIGS. 27A and 27B.

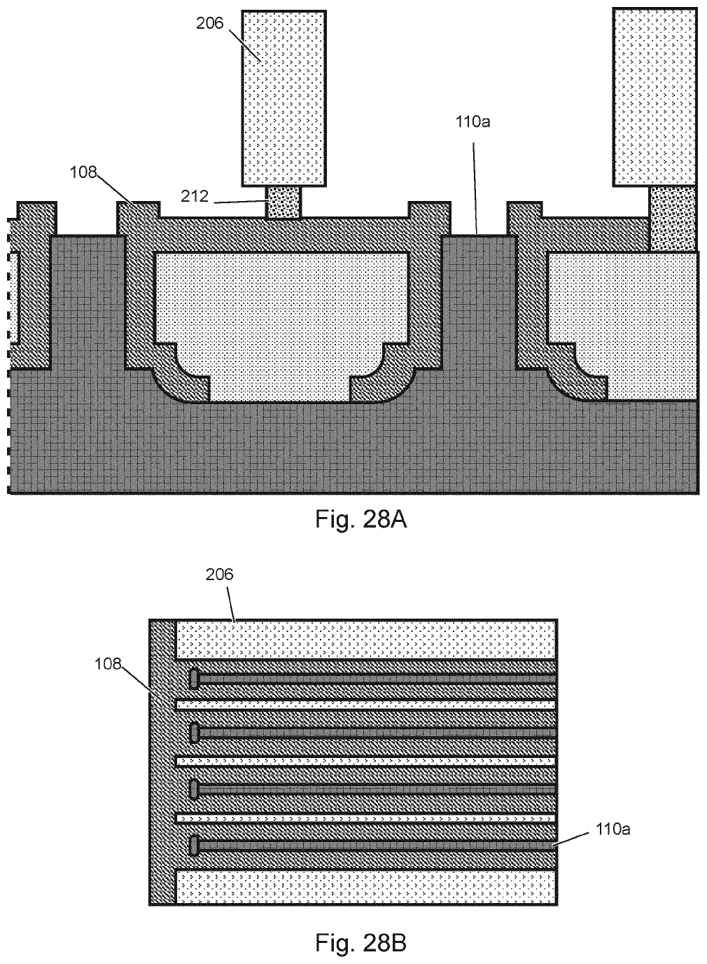

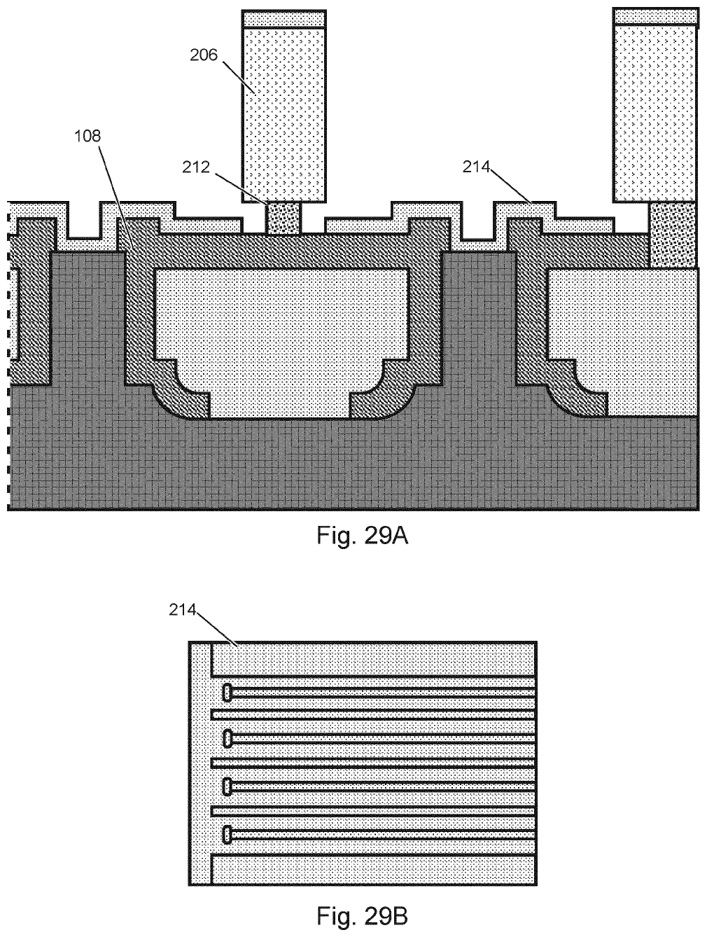

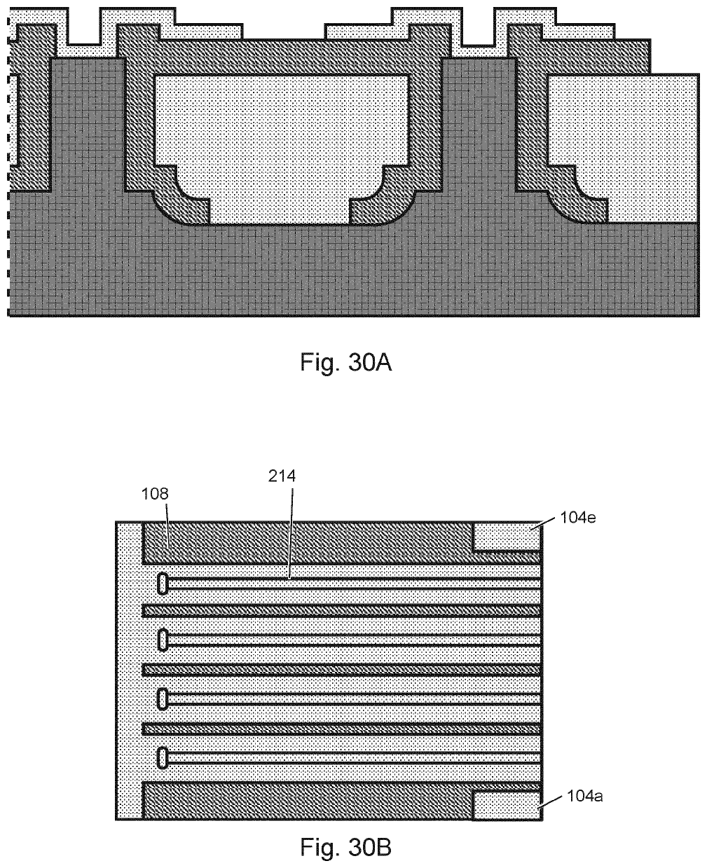

Next, in a step shown in FIGS. 28A and 28B, further PMGI 212 and photoresist 206 is provided in preparation of providing the upper metal contacts. The PMGI 212 is provided with a thickness, generally centrally above the lower metal contacts and separated therefrom by the insulator 108. The photoresist 206 is provided above the PMGI 212, with a second thickness greater than the thickness of PMGI. In a further step, shown in FIGS. 29A and 29B, metal 214 is deposited over the exposed upper surfaces with the exception of the insulator 108 shadowed by the PMGI 212 and photoresist 206. Therefore a plurality of discrete, non-contiguous metal portions are provided over each of the waveguides 110a-d. In one example, the metal has previously been covered with a III-V based protective cap (e.g. InP). This protective cap can then be removed using a selective etch, revealing the (pristine) contacts beneath. In an alternative, a short wet etch could be performed to remove oxidised layers on top of the contact layer. The PMGI and photoresist is then removed, as shown in FIGS. 30A and 30B.

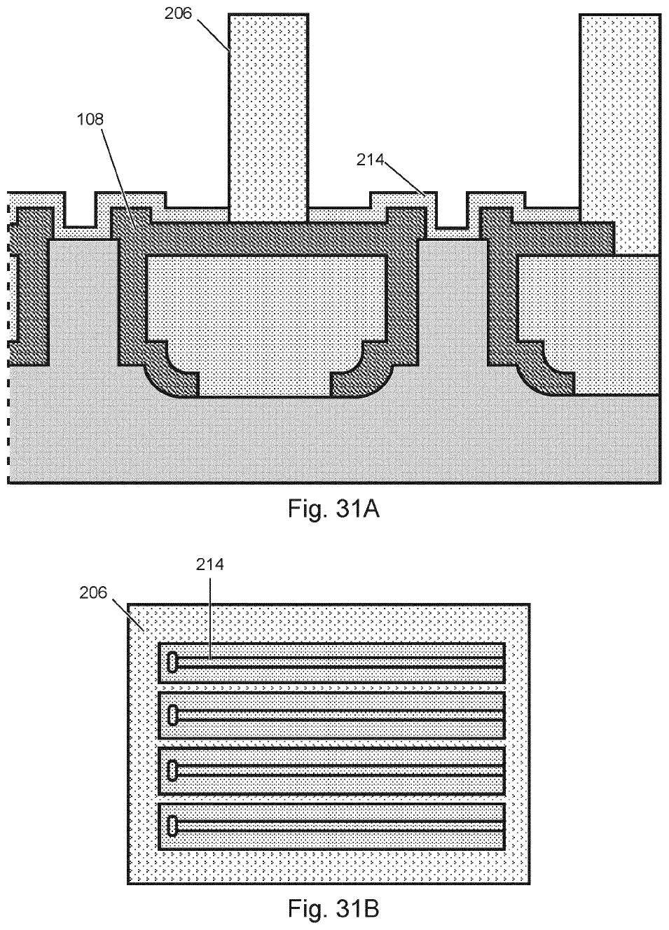

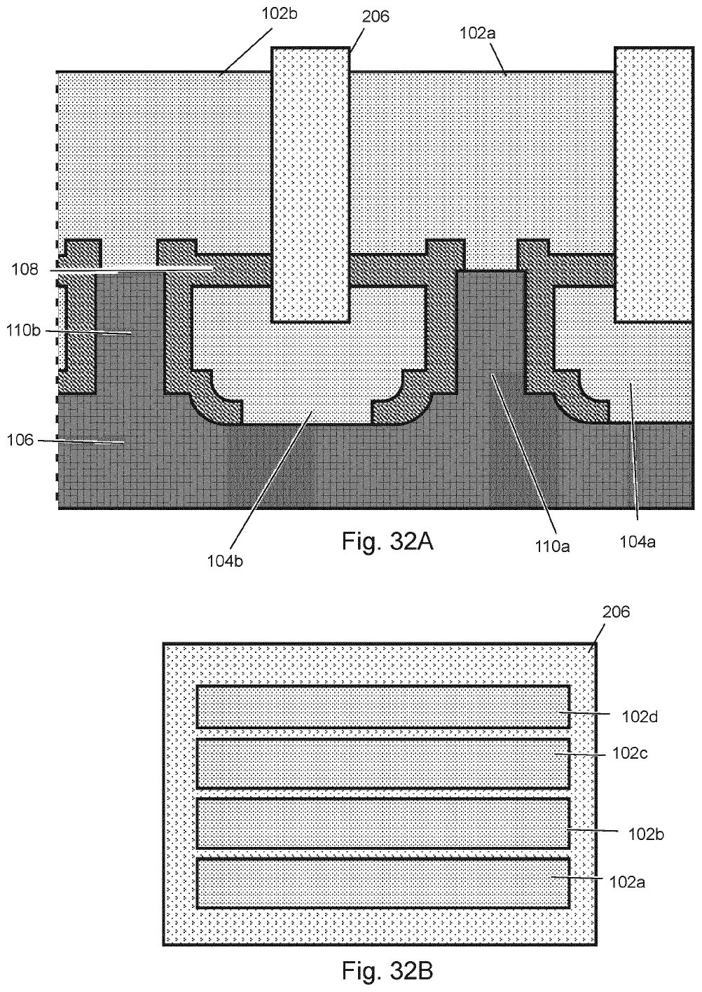

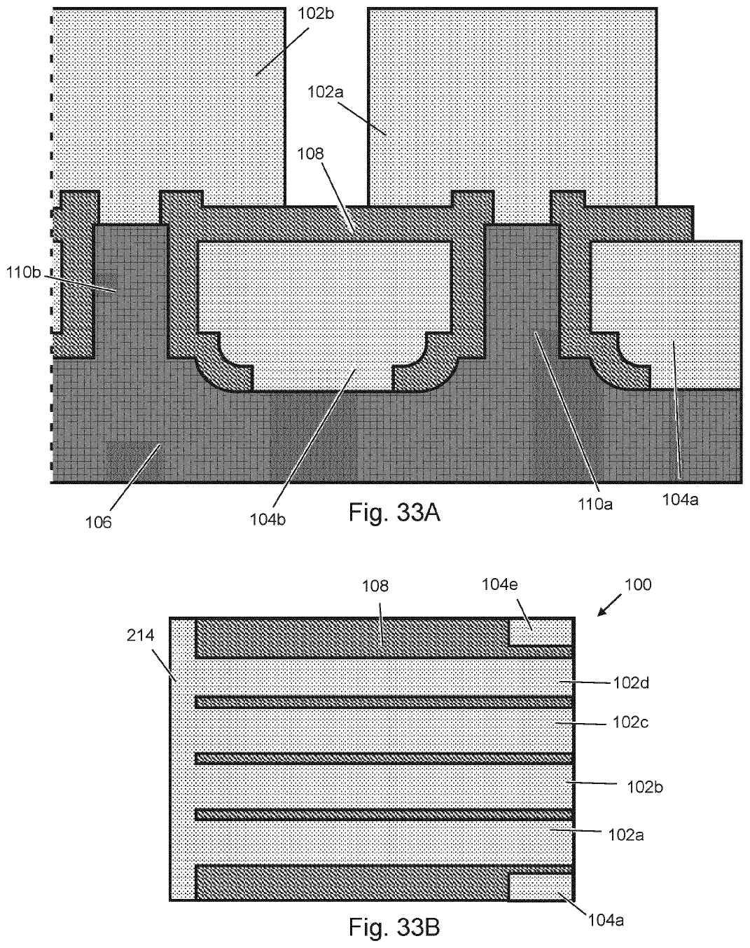

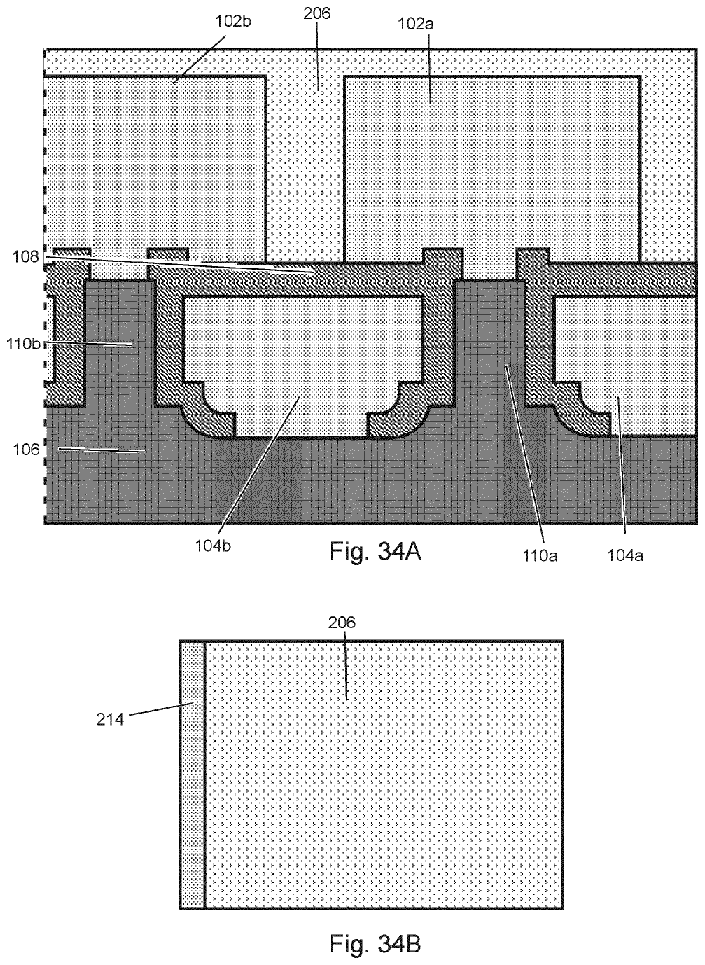

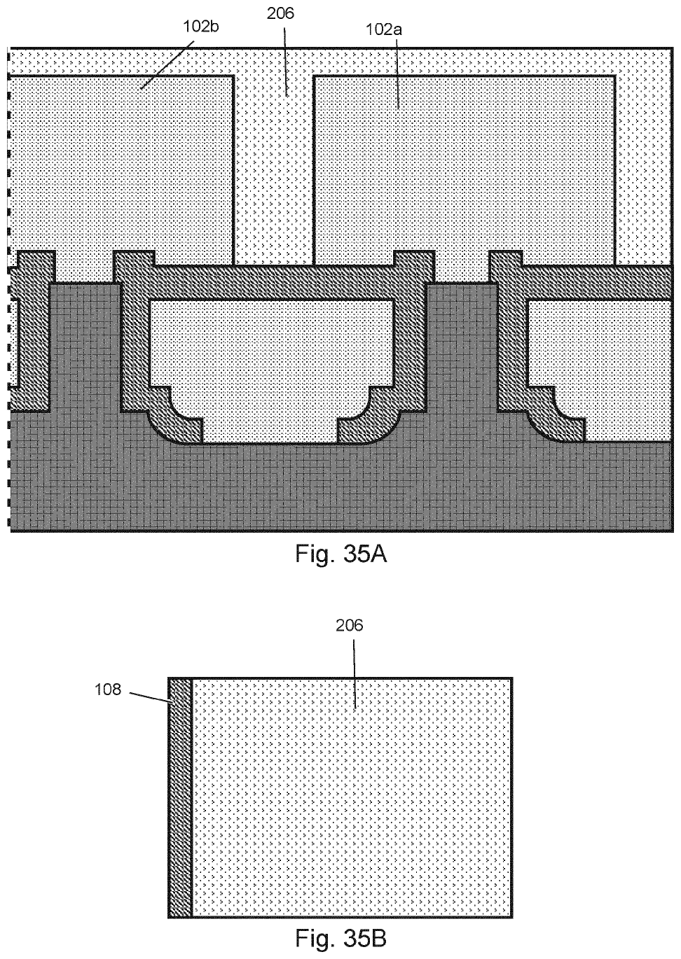

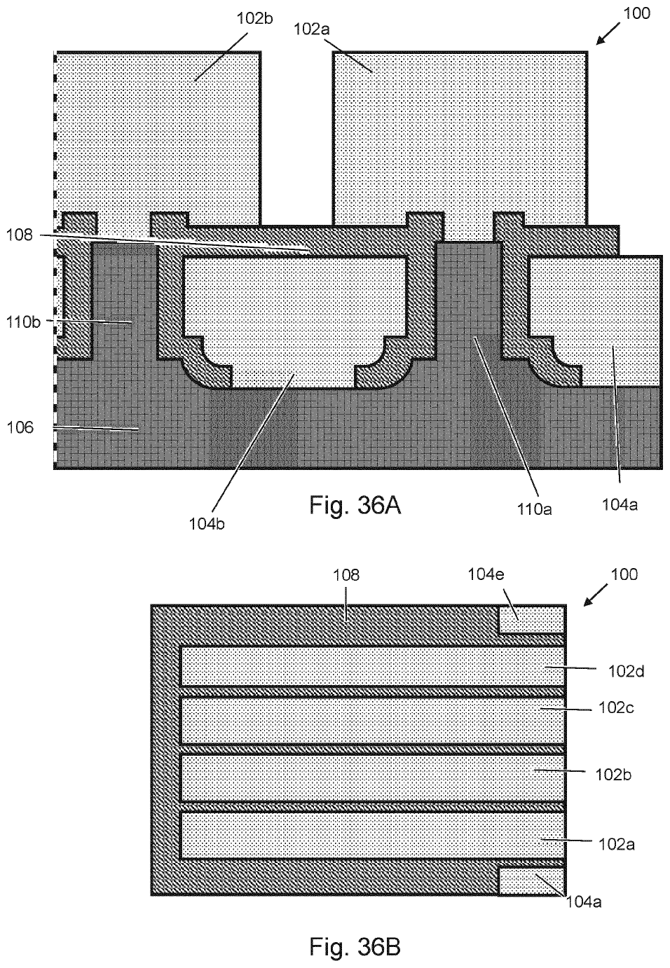

Further photoresist 206 is then deposited, as shown in FIGS. 31A and 31B, to constrain the metal which is provided subsequently. The existing, exposed, metal 214 is then plated to provide the upper metal contacts 102a-102d as shown in FIGS. 32A and 32B. In this example the upper metal contacts have a thickness of around 2 μm and are the p-contacts. The photoresist is then removed, as shown in FIGS. 33A and 33B. Further photoresist 206 is then applied to cover the bulk of the device, leaving metal portion 214 exposed (see FIGS. 34A and 34B specifically). The metal portion is then removed, as shown in FIGS. 35A and 35B, so that the insulator 108 is the uppermost layer. The photoresist is then removed, resulting in the final device shown in FIGS. 36a and 36B.

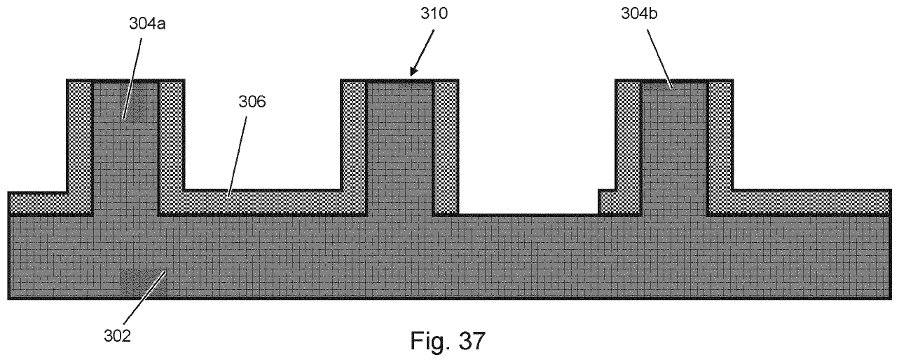

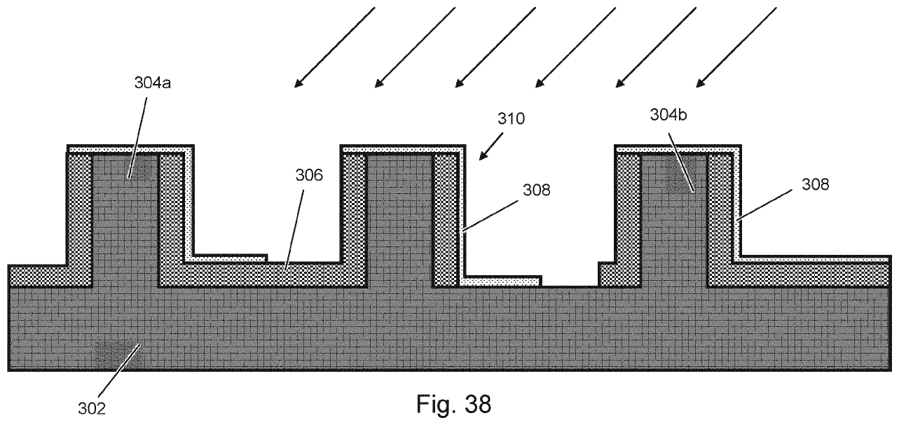

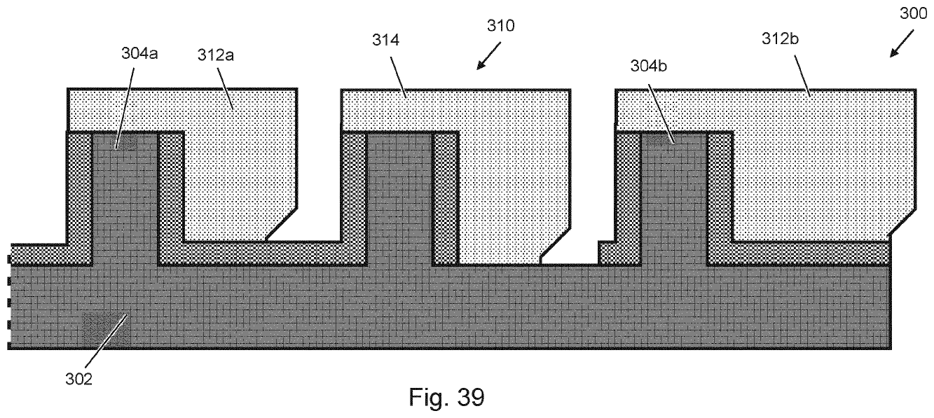

FIGS. 37-39 show various process steps of a variant optoelectronic device in cross-section. In a first step, shown in FIG. 37, a separator wall 310 is added between a pair of waveguide/laser ridges 304a and 304b. A window is then opened through an insulator 306, to expose a region of the semiconductor bed or substrate 302 located between the separator wall and a waveguide/laser ridge 304b. An angled deposition metal process, for example a 45° angled static evaporation process, is performed using the ridges to shadow parts of the device. This is shown in FIG. 38 where seed metal 308 is provided over portions of the device (this can be performed as described earlier, through the use of a PMGI layer and photoresist used in a lift-off step). Subsequently, an angled electroplating process is performed as shown in FIG. 39. This provides the plurality of upper metal contacts 312a and 312b, as well as the lower metal contact(s) 314 located between pairs of upper metal contacts. The upper metal contacts 312a, 312b electrically connect to upper surfaces of the waveguide/laser ridges 304a and 304b, whilst the lower metal contact(s) 314 electrically connect to the semiconductor bed (through a via in the insulating layer 306 at the bottom right of the separate wall 310).

Advantageously, this allows for the provision of both the upper and lower metal contacts in a single deposition step and so may be an overall more simple process. It further allows for all of the metal lines to be provided at the same altitude (relative to the semiconductor bed) which facilitates integration into a larger system, especially if other components/materials are to be added on top of it.

The features disclosed in the description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

### LIST OF FEATURES

100, 300 Optoelectronic device
102a-102d Upper metal contact
104a-104e Lower metal contact
106 Semiconductor substrate
108 Insulator
110a-110d Semiconductor waveguide
202 Semiconductor
204 Oxide hard mask
206 Photoresist
210 Insulator
212 Polydimethylglutarimide
214 Metal
302 Semiconductor substrate
304a, b Laser
306 Insulator
308 Metal
310 Separator wall
312a, b Upper metal contact
314 Lower metal contact

1. An optoelectronic device, comprising:
a plurality of waveguide ridges provided in an array, each waveguide ridge extending away from a semiconductor bed;
a plurality of upper contacts, each electrically connected to an upper surface of a respective waveguide ridge, said upper surface being located distal from the semiconductor bed; and
a plurality of lower contacts, each located between a respective pair of waveguide ridges and electrically connected to the semiconductor bed.

2. The optoelectronic device of claim 1, wherein each waveguide ridge provides a laser gain medium such that, when coupled to a corresponding grating, a plurality of distributed feedback lasers or distributed Bragg-reflector lasers are formed.

3. The optoelectronic device of claim 1 or claim 2, wherein each upper contact is spaced from a respective lower contact by an insulating layer.

4. The optoelectronic device of claim 3, wherein the insulating layer is a dielectric.

5. The optoelectronic device of any preceding claim, wherein each lower contact is separated from the respective pair of waveguide ridges by an insulating layer.

6. The optoelectronic device of claim 5, wherein each lower contact and its respective insulating layer fill the space between the respective pair of waveguide ridges.

7. The optoelectronic device of claim 5 or 6, wherein the insulating layer is a dielectric.

8. The optoelectronic device of any preceding claim, wherein each upper contact is situated on an opposing side of its respective waveguide ridge to the semiconductor bed.

9. The optoelectronic device of claim 7, wherein each upper contact has a width which is wider than a corresponding width of its respective waveguide ridge.

10. The optoelectronic device of any preceding claim, wherein each lower contact is electrically connected to one or more contact pads, said or each contact pad having an exposed surface suitable for connection to an external driver.

11. The optoelectronic device of claim 1 or 2, wherein each pair of waveguides ridges is separated by a respective separator wall, and each lower contact is adjacent to at least a portion of a respective separator wall.

12. The optoelectronic device of any preceding claim, wherein each upper and/or each lower contact has a width of at least 15 μm, said width may be measured in a direction transversal to a guiding direction of the plurality of waveguide ridges.

13. The optoelectronic device of any preceding claim, wherein each upper contact extends through an opening in an insulating layer to electrically connect to the upper surface of each waveguide ridge.

14. The optoelectronic device of any preceding claim, wherein each upper and/or each lower contact has a height of at least 1.5 μm, said height may be measured in a direction from the semiconductor bed towards the upper contact.

15. The optoelectronic device of any preceding claim, wherein each upper contact is electrically isolated from the other upper contacts.

16. The optoelectronic device of any preceding claim, wherein each lower contact is in electrical connection with the other lower contacts.

17. The optoelectronic device of any preceding claim, wherein the upper contacts and/or lower contacts are made of metal.

18. The optoelectronic device of any preceding claim, wherein the upper contacts and/or lower contacts are made from a doped semiconductor.

19. A method of preparing an optoelectronic device, the optoelectronic device comprising a plurality of waveguide ridges provided in an array, each waveguide ridge extending away from a semiconductor bed; the method comprising steps of:
(a) depositing a plurality of lower contacts, each located between a respective pair of waveguide ridges and electrically connected to the semiconductor bed; and
(b) depositing a plurality of upper contacts, each electrically connected to an upper surface of a respective waveguide ridge, said upper surface being located distal from the semiconductor bed.

20. The method of claim 19, further including a step, performed before step (a), of growing an insulator on an exposed surface of the optoelectronic device, and etching an opening in the insulator, exposing a surface of the semiconductor bed, for each lower contact to be deposited in during the subsequent deposition step.

21. The method of claim 19 or 20, wherein step (a) includes an initial step of providing a liner at least partially up a sidewall of each waveguide ridge, and along the semiconductor bed between respective pairs of waveguide ridges.

22. The method of claim 21, wherein step (a) further includes a step of depositing further contact material on at least the liner such that each lower contact and a respective insulating layer, the insulating layer being located between the lower contact and its respective pair of waveguide ridges, fill the space between the respective pair of waveguide ridges.

23. The method of any of claims 19-22, wherein step (b) is performed after step (a) and includes an initial step of growing an insulator layer over the plurality of lower contacts.

24. The method of claim 23, wherein the insulator layer is also grown over the upper surfaces of each waveguide ridge, and step (b) further includes etching an opening in the insulator layer to expose the upper surface of each waveguide ridge, said etching occurring before the deposition of the upper contacts.

25. The method of claim 19, wherein steps (a) and (b) are performed in a simultaneous deposition step.

26. The method of claim 25, wherein the simultaneous deposition step is performed through angled electroplating, and wherein a plurality of separator walls, each provided between a respective pair of waveguide ridges, provides a shadow over at least a part of a space between each separator wall and one of the respective pair of waveguide ridges, such that a gap exists between each lower contact and respectively adjacent upper contacts.

27. The method of any of claims 19-26, wherein the upper contacts and/or lower contacts are made of metal.

28. The optoelectronic device of any of claims 19-26, wherein the upper contacts and/or lower contacts are made from a doped semiconductor.

29. An optoelectronic device, prepared using the method of any of claims 19-28.
